(19) United States
(12) Patent Application Publication
(10) Pub. No.: US 2009/0092858 A1
(43) Pub. Date: Apr. 9, 2009

(54) PERPENDICULAR MAGNETIC RECORDING FILM MEDIUM AND METHOD OF MANUFACTURING THE SAME

(75) Inventors: Sheng-Chi Chen, Taipei (TW); Po-Cheng Kuo, Taipei (TW); Chi-Long Shen, Taipei (TW); Shang-Lin Hsu, Taipei (TW); Ching-Ray Chang, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Sheng-Chi Chen, Taipei (TW)

(21) Appl. No.: 12/130,087

(22) Filed: May 30, 2008

(30) Foreign Application Priority Data
Oct. 5, 2007 (TW) 096137609

(51) Int. Cl. G11B 5/62; B05D 3/00; C23C 14/35

(52) U.S. Cl. 428/846.9; 428/800; 428/846.1; 427/130; 204/192.2; 204/192.15

(57) ABSTRACT

The perpendicular magnetic recording medium of the present invention includes a substrate, a non-magnetic layer, a ferromagnetic layer and an antiferromagnetic oxide. The non-magnetic layer is formed on the substrate and the ferromagnetic layer is formed on the non-magnetic layer. The antiferromagnetic oxide is formed in the ferromagnetic layer after the perpendicular magnetic recording medium is annealed by an annealing process. An exchange coupling interaction between the antiferromagnetic oxide and the ferromagnetic materials is introduced.

### FIELD OF THE INVENTION

The present invention relates to a magnetic recording medium, especially to a high density magnetic recording medium having high perpendicular magnetic properties and low ordering temperature.

### BACKGROUND OF THE INVENTION

As the information technology industry was developing, data storage capacities of various softwares and medium file formats became larger and larger. A magnetic recording medium for storing data, such as a harddisk, was improved to provide the most advancing technology. There was a trend that the storage capacities of the medium became larger. The goal of R&D departments of harddisk companies and academic research centers was to develop a magnetic recording medium having more storage capacity.

Many technological revolutions of the harddisks improved the manufacture of the harddisks to meet the user's needs. The main stream of storing data by using a magnetic recording medium was a longitudinal recording technology.

Generally, the so-called harddisk was made by using a substrate made of a material, such as aluminum metal, glass, etc. A magnetic material, such as CoCrPtB alloy, was covered on the outset layer of the substrate by sputtering or evaporation method to form a magnetic film for recording data.

The conventional harddisk adopted longitudinal recording for storing data. By longitudinal recording, the stored bits adjacent to each other were aligned in opposite magnetization orientation and limited by superparamagnetic limit. When a recording density increased to some extent, the written data would lose due to thermal unstability.

The development of longitudinal recording approached its limit to meet market big needs. Recently, recording media by using perpendicular recording were gradually commercially available in the harddisk market. A feature of the perpendicular recording is that the magnetization direction of the recording media was perpendicular to harddisk film surface. Because the demagnetizing field of the perpendicular recording was smaller and the recording layer of it was thicker, the perpendicular recording was considered as a better solution to overcome the drawback of thermal unstability of the longitudinal recording and to increase the bit density of the harddisk. Because the magnetization orientations of two adjacent bits for the perpendicular recording were parallel to each other and in opposite directions, which would achieve ultra high areal recording density to be used as a next generation recording medium technology.

A first theory of the perpendicular recording was invented by Danish scientist, Mr. Valdemar Poulsen (1869-1942) at the end of the 19^{th} century and steel lines were used as a material of the perpendicular recording. The materials used and the process of manufacturing should be suitably selected to apply the perpendicular recording technology to accurately record, read and write. The materials used in perpendicular recording technology were CoCrPt series of alloy film materials.

A high coercivity is a property which a magnetic film material having a high recording density must have. To obtain a high coercivity, a material with a high magnetocrystalline anisotropy constant (Ku) was used to prevent magnetization reversal. The recording material of CoCrPt alloy with a Ku value of 2×10⁶ erg/cm³ that could not meet the requisite of the high coercivity. Therefore, to develop a material having more higher Ku than the CoCrPt series alloy film is important to produce an ultra high areal recording density medium of the next generation.

The so-called high Ku constant materials had been found, for example, FePt and CoPt which respectively has a high Ku value of 7×10⁷ erg/cm³ and 5×10⁷ erg/cm³. The perpendicular magnetic anisotropy of FePt (CoPt) could be obtained from a multilayer structures consisting of MgO underlayer, Pt buffer layer, and FePt (CoPt) magnetic layer. However, the Ll₀ FePt (CoPt) had a high ordering temperature of more than 500° C., which is higher the processing temperature of 300° C. for current harddisk and results in the mutual diffusion between the multilayers to decrease the magnetic properties of the magnetic recording film. On the other hand, the Kμ value of hcp Co₇₅Pt₂₅ alloy film is also as high as 2×10⁷ erg/cm³ and its cost is cheaper than that of CoPt due to its Pt content is less than CoPt. Furthermore, the manufacture temperature of Co₇₅Pt₂₅ film for yielding high perpendicular magnetic anisotropy and high saturated magnetization is only 300° C., which is consistent with the current harddisk manufacture temperature.

From the above, to improve the drawbacks of the conventional magnetic recording film is a subject to be solved in the art. The inventor of the present invention figured out a recording medium having low process temperature, a simple film structure and high perpendicular magnetic properties and the process of manufacturing the same to be used as the perpendicular recording material.

### SUMMARY OF THE INVENTION

According to one aspect of the present invention, the present invention provide a perpendicular magnetic recording medium comprising:

a substrate;

a non-magnetic layer formed on the substrate;

a ferromagnetic layer formed on the non-magnetic layer; and an antiferromagnetic oxide generated in ferromagnetic layer by an annealing process and the exchange coupling interaction between the antiferromagnetic oxide and ferromagnetic materials

wherein the perpendicular magnetic recording medium achieves a high perpendicular magnetic properties via the exchange coupling.

Preferably, the substrate is made of one of a glass and a silicon.

Preferably, the non-magnetic layer is made of a metal having a face-centered cubic (fcc) structure.

Preferably, the non-magnetic layer is made of a material selected from a group consisting of platinum, palladium, gold, silver, copper, nickel, rhodium, iridium and a combination thereof.

Preferably, the non-magnetic layer has a thickness of between 20 nm and 200 nm.

Preferably, the ferromagnetic layer is a cobalt-based alloy made of a cobalt-platinum alloy.

Preferably, the cobalt-platinum alloy has a cobalt content between 65 at % and 85 at %.

Preferably, the ferromagnetic layer has a thickness between 5 nm and 40 nm.

Preferably, the perpendicular magnetic properties include a perpendicular coercivity, a saturated magnetization and a perpendicular squareness.

Preferably, the perpendicular coercivity is larger than 3000 Oe.

Preferably, the saturated magnetization is larger than 600 emu/cm³.

Preferably, the perpendicular squareness is larger than 0.8.

According to another aspect of the present invention, the present invention provides a method of manufacturing a perpendicular magnetic recording film medium comprising steps of:

(a) providing a substrate;

(b) forming a non-magnetic layer on the substrate;

(c) forming a ferromagnetic layer on the non-magnetic layer; and

(d) annealing the ferromagnetic layer to form an antiferromagnetic oxide in the ferromagnetic layer.

Preferably, the non-magnetic layer in the step (b) is formed by a magnetron sputtering method.

Preferably, the ferromagnetic layer in step (c) is formed by a magnetron sputtering method.

Preferably, an annealing temperature in the step (d) is between 275° C. and 400° C.

Preferably, the annealing in step (d) is carried out in a vacuum of 0.1 mTorr to 20 mTorr.

Preferably, an annealing time in step (d) is between 5 minutes and 60 minutes.

According to another aspect of the present invention, the present inventions pro vides a perpendicular magnetic recording medium comprising:

a substrate;

a non-magnetic layer formed on the substrate;

a ferromagnetic layer formed on the non-magnetic layer; and

an antiferromagnetic oxide is formed in ferromagnetic layer by an annealing process and generating an exchange coupling with the ferromagnetic materials.

Preferably, the annealing process is performed after the ferromagnetic layer formed.

The foregoing and other features and advantages of the present invention will be more clearly understood through the following descriptions with reference to the drawings, wherein:

### BRIEF DESCRIPTION OF THE DRAWINGS

FIG. 1 is a cross-sectional view of layer structure of an embodiment of a perpendicular magnetic recording film medium of the present invention;

FIG. 2 is a cross-sectional view of layer structure of a comparative example of a magnetic recording film medium according to the prior art;

FIG. 3 is chart showing a variation of the perpendicular coercivity Hc⊥ after the perpendicular magnetic recording film medium of the preferred embodiment of the present invention and the recording medium of the comparative example of prior art are annealed at different temperatures for 30 minutes;

FIG. 4 is an XRD diffraction curve chart of the perpendicular magnetic recording medium of the preferred embodiment of the present invention and the recording medium of the comparative example of prior art annealed at a temperature of 300° C. for 30 minutes;

FIG. 5(a) is a hysteresis loop chart of Vibrating Sample Magnetometer (VSM) of the perpendicular magnetic recording film medium of the present invention which is annealed at a temperature of 300° C. for 30 minutes;

FIG. 5(b) is a hysteresis loop chart of Vibrating Sample Magnetometer (VSM) of the recording medium of the comparative example which is annealed at a temperature of 300° C. for 30 minutes

FIG. 6(a) is an Auger Electron Spectroscopy (AES) elements depth profiles of the perpendicular magnetic recording film medium of the present invention which is annealed at a temperature of 300° C. for 30 minutes

FIG. 6(b) is an Auger Electron Spectroscopy (AES) elements depth profiles of the recording medium of the comparative example which is annealed at a temperature of 300° C. for 30 minutes

FIG. 7(a) is an X-Ray photoelectron spectrometry of the perpendicular magnetic recording film medium of the present invention which is annealed at a temperature of 300° C. for 30 minutes; and

FIG. 7(b) is an X-Ray photoelectron spectrometry of the recording medium of the comparative example which is annealed at a temperature of 300° C. for 30 minutes.

### DETAILED DESCRIPTION OF THE PREFERRED EMBODIMENT

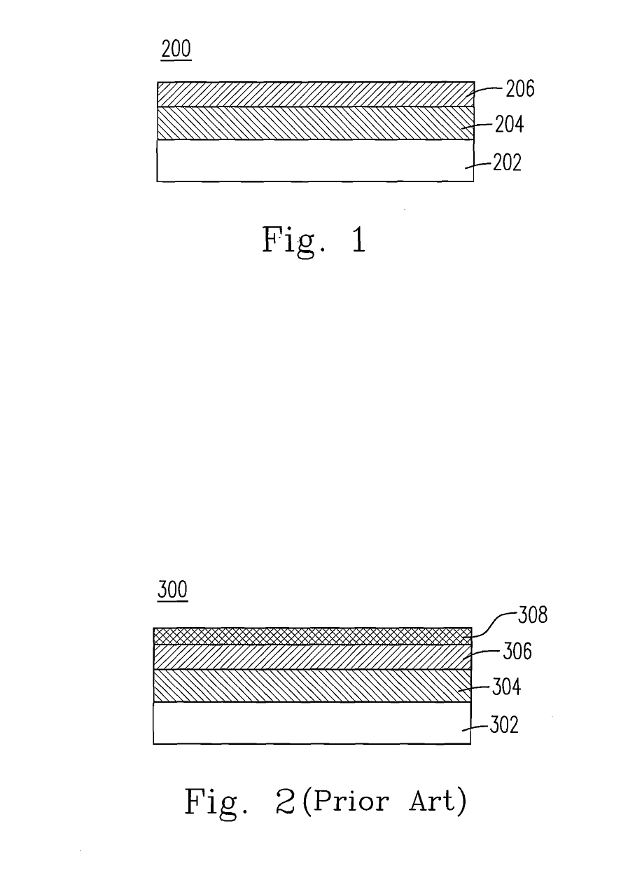

The present invention will now described more specifically with reference to the following embodiments. Please refer to FIG. 1 which is a cross-sectional view of layer structure of an embodiment of a perpendicular magnetic recording medium 200 of the present invention. The perpendicular magnetic recording medium 200 includes a glass substrate 202, a non-magnetic underlayer 204 and a ferromagnetic layer 206.

The substrate 202 can be prepared by using a glass or silicon. In this embodiment of the present invention, the glass is used as a material of the substrate 202. The non-magnetic layer 204 is formed by direct current (dc) magnetron sputtering on a side of the substrate 202. A material of the non-magnetic layer 204 is selected from a group consisting of platinum, palladium, gold, silver, copper, nickel, rhodium and iridium. The platinum is used in the present embodiment and the non-magnetic layer 204 can be called as platinum non-magnetic layer 204. The non-magnetic layer 204 has a thickness between 20 nm and 200 nm, preferably 100 nm in the present embodiment of the present invention.

The ferromagnetic layer 206 is formed by dc magnetron co-sputtering on the non-magnetic layer 204. A material of the ferromagnetic layer 206 is cobalt-platinum alloy film which contains cobalt and platinum. The cobalt content in the cobalt-platinum alloy is between 65 at %: and 85 at %, preferably Co₇₅Pt₂₅. The ferromagnetic layer 206 is called as cobalt-rich cobalt-platinum ferromagnetic layer 206 with a thickness of 5 nm to 40 nm, preferably 15 nm in the present embodiment.

A side of the ferromagnetic layer 206 is annealed at a temperature of 275° C. to 400° C. in a vacuum of 0.1 mTorr to 20 mTorr for 5 minutes to 60 minutes to generate an antiferromagnetic oxide in ferromagnetic layer. The antiferromagnetic oxide induces an exchange coupling interaction with the ferromagnetic materials to enhance a perpendicular hard magnetic properties of the recording medium.

A sputtering power of the ferromagnetic layer 206 is controlled at 60 watt for cobalt target and 5 watt for platinum target. A sputtering power of the platinum non-magnetic layer 204 is controlled at 5 watt, the temperature of glass substrate 202 is at ambient temperature, an argon pressure of sputtering chamber is controlled at 10 mTorr, and the rotating speed of the substrate 202 is fixed at 10 rpm. The as sputtered films are annealed at temperatures in the range of 275° C. to 400° C. for 30 minutes under a vacuum of 1 mTorr, then cooling at the annealing furnace.

Please refer to FIG. 2 which is a cross-sectional view of layer structure of a recording medium 300 of a comparative example of prior art. A protection layer is formed by dc magnetron sputtering on a ferromagnetic layer in order to avoid oxidation of the magnetic recording layer. As shown in FIG. 2, the recoding medium 300 of the comparative example includes a protection layer 308, a ferromagnetic layer 306, a underlayer 304 and a glass substrate 302. The sputtering power of the ferromagnetic layer 306 having a thickness of 15 nm is controlled at 60 watt for cobalt target and at 5 watt for platinum target. A sputtering power of the platinum protection layer 308 having a thickness of 5 nm and the platinum underlayer 304 with a thickness of 100 nm is controlled at 5 watt, the temperature of the glass substrate 302 is at ambient temperature, an argon pressure of sputtering chamber is controlled at 10 mTorr, and the rotating speed of the glass substrate 302 is fixed at 10 rpm. The as sputtered films are annealed at temperatures in the range of 275° C. to 400° C. for 30 minutes under a vacuum of 1 mTorr, then cooling at the annealing furnace.

According to a schematic TEM cross-sectional view of the perpendicular magnetic recording medium of the preferred embodiment of the present invention, a ferromagnetic layer shows epitaxial growth on a platinum underlayer. A Pt(111) underlayer is related closely to the epitaxial effect which could induce a preferred orientation of the Co—Pt(002) of the ferromagnetic layer to form perpendicular magnetic anisotropy. From the schematic TEM cross-sectional view, it is clear that a non-magnetic underlayer having a thickness of 100 nm and a ferromagnetic layer with a thickness 15 nm disposed thereon.

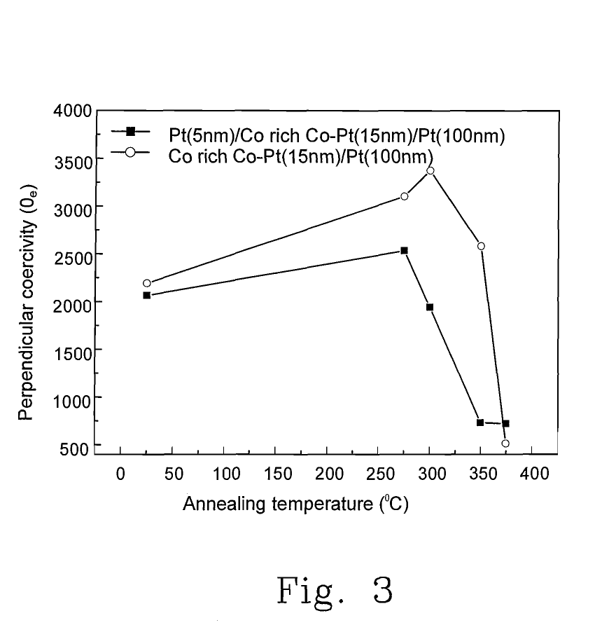

Please refer to FIG. 3 which shows a variation of the perpendicular coercivity Hc⊥ after the perpendicular magnetic recording medium 200 of the preferred embodiment of the present invention and the recording medium 300 of the comparative example of prior art are annealed at different temperatures for 30 minutes. It is found that the perpendicular coercivity Hc⊥ of the preferred embodiment of the present invention is larger than that of the comparative example except annealing at 375° C. For example, at a temperature of 300° C., the perpendicular coercivity Hc⊥ of the preferred embodiment is 3375 Oe. However, it is 1900 Oe for comparative example which is much less than that of the preferred embodiment. Because at annealing temperature of 300° C. generates a stronger oxidation effect to form more cobalt oxide (CoO) in ferromagnetic layer 206 and an exchange coupling interaction between the antiferromagnetic cobalt oxide and the ferromagnetic materials is introduced to increase the perpendicular coercivity.

Furthermore, in FIG. 3, when the annealing temperature is larger than 350° C., many platinum atoms of the platinum, protection layer 308 and the platinum underlayer 304 diffuse into the grain boundary of the cobalt rich Co—Pt layer 306 to increase a grain boundary energy such that a hexagonal closed-packed (hcp) structure of the ferromagnetic layer 306 changes its phase into a face-centered cubic (fcc) structure that will decrease the Hc⊥ value of ferromagnetic layer 306. On the other hand, part of platinum atoms will diffuse to the grain surface area of the ferromagnetic layer 306 to change composition to approach equiatomic Co₅₀Pt₅₀, which also decrease the Hc⊥ value at 350° C.

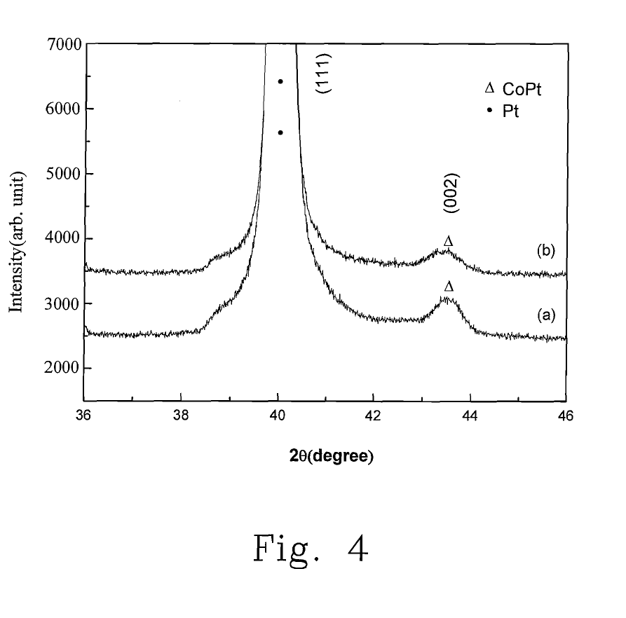

Please refer to FIG. 4 which is an XRD diffraction curve chart of the perpendicular magnetic recording medium 200 of the preferred embodiment of the present invention and the recording medium 300 of the comparative example of prior art are annealed at a temperatures of 300° C. for 30 minutes. In FIG. 4, a curve (a) is the comparative example and a curve (b) is the preferred embodiment. According to FIG. 4, Pt(111) of the non-magnetic layer 204 having a fcc structure shows a diffraction peak at 39.60 while Co—Pt(002) of the ferromagnetic layer 206 having a hcp structure shows a diffraction peak at 43.6°. From FIG. 4 it is known that if the ferromagnetic layer 206 has perpendicular magnetic anisotropy, a Co—Pt(002) diffraction peak appears and a Pt(111) diffraction peak having a strong intensity is observed. That is to say, the strong Pt(111) diffraction peak induces the Co—Pt(002) diffraction peak to form perpendicular magnetic anisotropy. The appearance of strong Pt(111) and Co—Pt(002) confirms that the perpendicular magnetic recording medium 200 of the present invention has perpendicular magnetic anisotropy.

From FIG. 4, it is known that the curve (a) of the recording medium of the comparative example and the curve (b) of the magnetic film medium of the preferred embodiment both have the strong Pt(111) and CoPt(002) diffraction peaks. But, the CoPt(002) diffraction peak of the comparative example is stronger than that of the preferred embodiment due to the part Co atoms of the ferromagnetic layer 206 of the preferred embodiment of the present invention oxidize to oxide of CoO after annealing at 300° C. under a vacuum of 1 mTorr. That is to say, the ratio of ferromagnetic materials in the ferromagnetic layer 206 of the preferred embodiment becomes less after annealing in comparison to the comparative example, so as to decrease the intensity of the Co—Pt(002) diffraction peak.

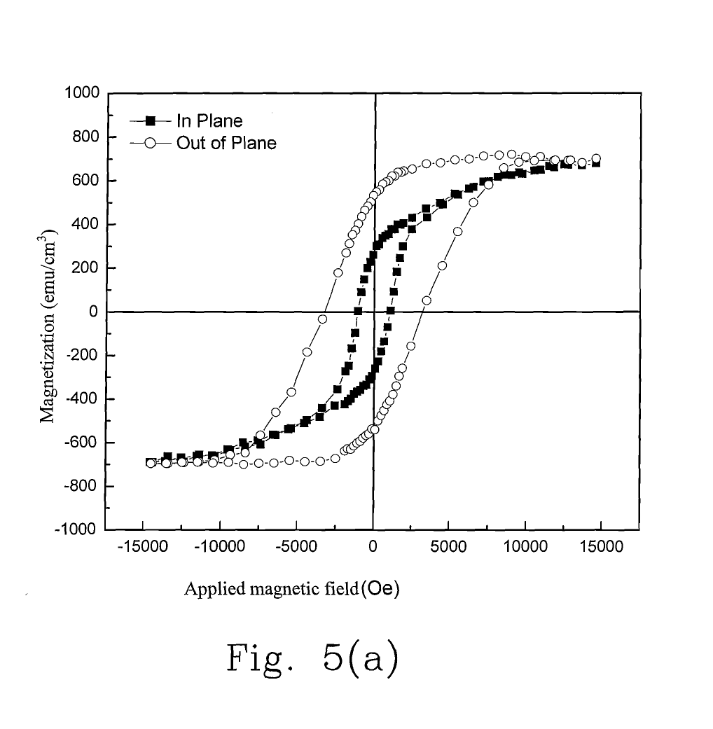

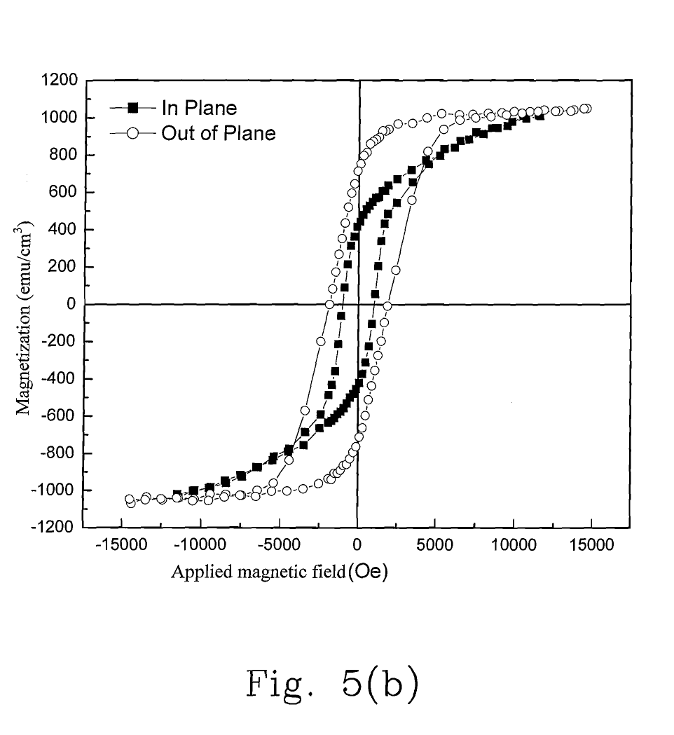

Please refer to FIGS. 5(a) and 5(b) which are respectively hysteresis loop charts of Vibrating Sample Magnetometer (VSM) of the perpendicular magnetic recording medium 200 of the present invention and the recording medium 300 of the comparative example after they are annealed at a temperature of 300° C. for 30 minutes. According to FIG. 5(a), a perpendicular coercivity Hc⊥ of the perpendicular magnetic recording film medium 200 of the present invention is between 3000-4000 Oe, a saturated magnetization Ms is between 600-700 emu/cm³ and a perpendicular squareness S⊥ is between 0.8-0.9. Because the oxidation effect in the perpendicular magnetic recording medium 200 of the present invention is stronger than that of recording medium 300 of the comparative example, more CoO is formed to induce the exchange coupling interaction between the antiferromagnetic CoO and the ferromagnetic materials, so as to increase the perpendicular hard magnetic properties of the present invention comparing FIG. 5(a) with FIG. 5(b), therefore, both the perpendicular coercivity and perpendicular squareness the of the perpendicular magnetic recording film medium 200 of the present invention are much larger than those of the recording medium 300 of the comparative example. Hence, the preferred embodiment can be better applied to the perpendicular magnetic recording medium than the comparative example.

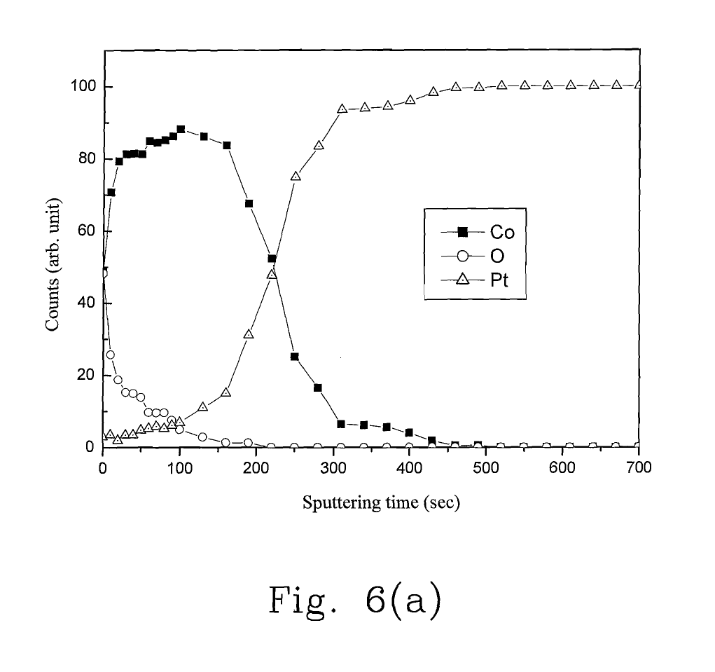

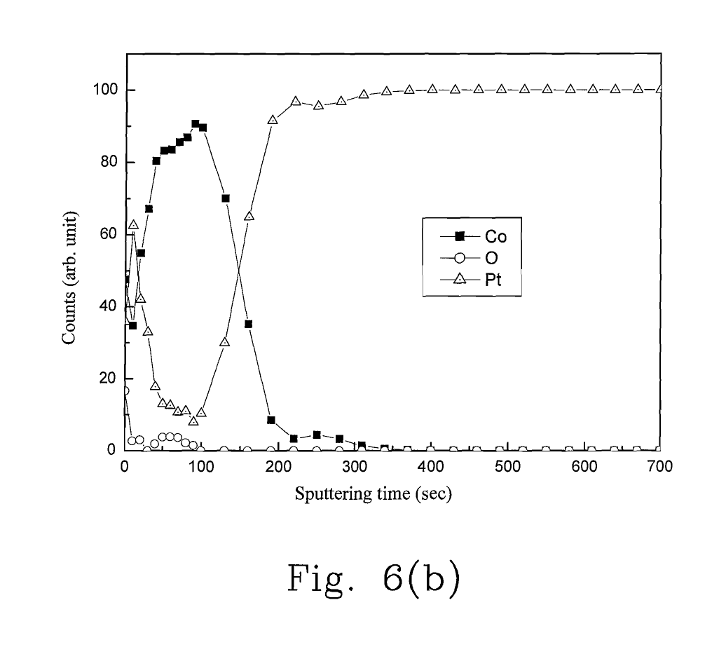

Please refer to FIGS. 6(a) and 6(b) which are respectively Auger Electron Spectroscopy (AES) charts of the perpendicular magnetic recording medium 200 of the present invention and the recording medium 300 of the comparative example after they are annealed at a temperature of 300° C. for 30 minutes. The high concentration of oxygen atoms are observed on a surface of the perpendicular magnetic recording medium 200 of the present invention. It is also found that the oxygen atoms content decrease as sputtering time goes on, which indicates the oxygen atoms gradually diffuse into inner layer of the cobalt rich Co—Pt ferromagnetic layer 206 after annealing at 300° C.

Please refer to FIG. 6(b) which shows that the oxygen atoms content on the surface and inner layer of ferromagnetic layer 306 of the recording medium 300 of the comparative example are much less than those of the preferred embodiment of the present invention. It implies that the Pt protection layer 308 of the comparative example could inhibit a formation of the antiferromagnetic CoO to decrease the exchange coupling interaction between the CoO and the ferromagnetic layer 306, which results in a lower perpendicular coercivity Hc⊥ as shown in FIG. 5(b).

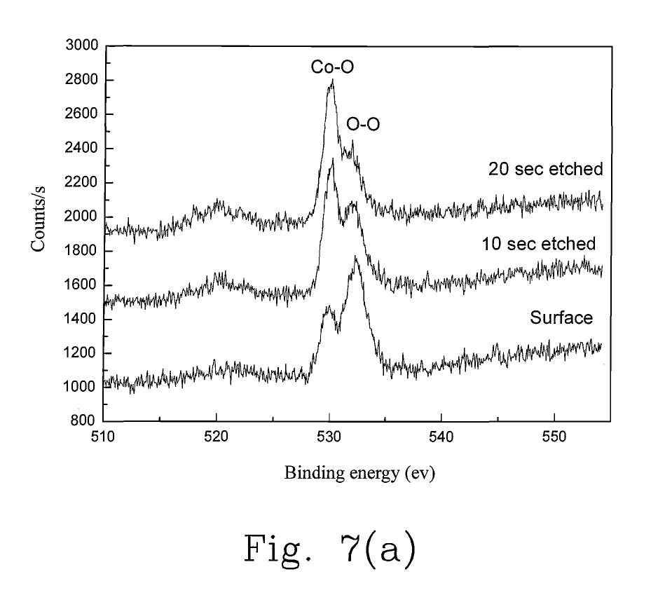

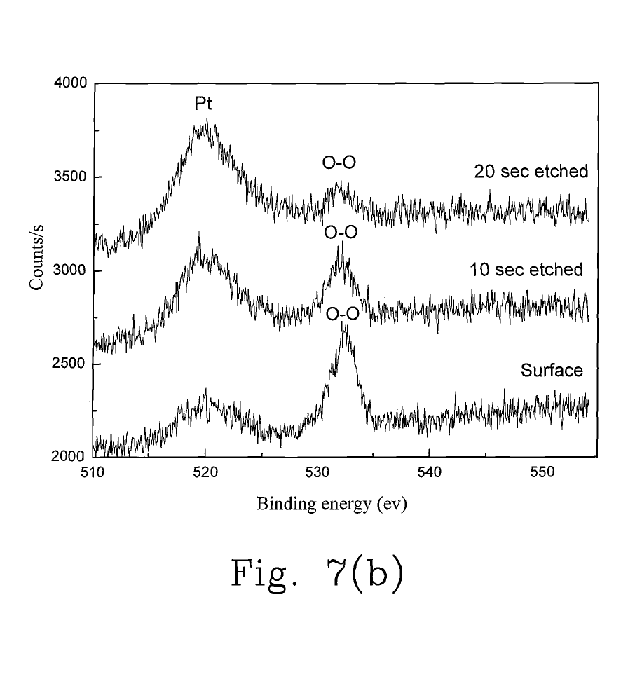

Please refer to FIGS. 7(a) and 7(b) which are respectively X-Ray photoelectron spectrometry of the perpendicular magnetic recording medium 200 of the present invention and the recording medium 300 of the comparative example after they are annealed at a temperature of 300° C. for 30 minutes. After the perpendicular magnetic recording medium 200 of the present invention is annealed at a temperature of 300° C., it is found that the bonding of the oxides is increased as the sputtering time goes on. That is to say, after annealing at temperature of 300° C., the oxygen atoms will diffuse into the more inner layer of the ferromagnetic layer 206 to form CoO with a sufficient cobalt atoms, so as to form more CoO oxide as increasing sputtering time. This results conform with an observation of the Auger Electron Spectroscopy chart of FIG. 6(a). The antiferromagnetic CoO oxide will generate the exchange coupling interaction with the ferromagnetic materials to increase the perpendicular coercivity as shown in the VSM hysteresis loop chart of FIG. 5(a).

According to FIG. 7(b), after the recording medium 300 of the comparative example is annealed at a temperature of 300° C., a large amount of oxygen atoms are detected at the surface. Because only few oxygen atoms diffuse into the ferromagnetic layer 306 due to excellent protection effect by protection layer, no CoO oxide is observed. Therefore, the perpendicular coercivity Hc⊥ is much lower as shown in FIG. 5(b). It is confirmed that the existing of the Pt protection layer 308 will inhibit the formation of CoO and lead to obtain a lower perpendicular coercivity Hc⊥.

Accordingly, in the preferred embodiment of the perpendicular magnetic recording medium 200 of the present invention, a simple dc magnetron sputtering method is used and the processing temperature is at 300° C., which is consistent with manufacturing temperature of current harddisk. On the other hand, the platinum content of the cobalt rich Co—Pt ferromagnetic layer 206 is between 15% and 35%. After it is compared to the Ll₀Co₅₀Pt₅₀ alloy film, the cost down due to noble metal of Pt is decreased and a better perpendicular magnetic properties are obtained by using the simply non-magnetic layer as an underlayer to simplify the layer structure and to decrease the inter-diffusion between multilayers. Therefore, in present invention, the perpendicular magnetic recording medium 200 with high perpendicular magnetic properties and low ordering temperature is achieved to apply to the perpendicular magnetic recording medium.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A perpendicular magnetic recording film medium, comprising:
a substrate;
a non-magnetic layer formed on the substrate;
a ferromagnetic layer formed on the non-magnetic layer; and
an antiferromagnetic oxide generated in the ferromagnetic layer by an annealing process;
wherein the perpendicular magnetic properties are improved from an exchange coupling interaction between the antiferromagnetic oxide and the ferromagnetic materials.

2. The perpendicular magnetic recording film medium according to claim 1, wherein the substrate is selected from one of a glass and a silicon.

3. The perpendicular magnetic recording medium according to claim 1, wherein the non-magnetic layer is made of a metal having a face-centered cubic (fcc) structure.

4. The perpendicular magnetic recording medium according to claim 3, wherein the non-magnetic layer is made of a material selected from a group consisting of platinum, palladium, gold, silver, copper, nickel, rhodium, iridium and a combination thereof.

5. The perpendicular magnetic recording medium according to claim 1, wherein the non-magnetic layer has a thickness between 20 nm and 200 nm n.

6. The perpendicular magnetic recording medium according to claim 1, wherein the ferromagnetic layer is a cobalt-platinum alloy.

7. The perpendicular magnetic recording medium according to claim 6, wherein the cobalt-platinum alloy has a cobalt content between 65 at % and 85 at %.

8. The perpendicular magnetic recording medium according to claim 1, wherein the ferromagnetic layer has a thickness between 5 nm and 40 nm.

9. The perpendicular magnetic recording medium according to claim 1, wherein the perpendicular film magnetic properties include a perpendicular coercivity, a saturated magnetization and a perpendicular squareness.

10. The perpendicular magnetic recording medium according to claim 9, wherein the perpendicular coercivity is larger than 3000 Oe.

11. The perpendicular magnetic recording medium according to claim 9, wherein the saturated magnetization is larger than 600 emu/cm³.

12. The perpendicular magnetic recording medium according to claim 9, wherein the perpendicular squareness is larger than 0.8.

13. A method of manufacturing a perpendicular magnetic recording medium, comprising steps of:
(a) providing a substrate;
(b) forming at least one non-magnetic layer on the substrate;
(c) forming at least one ferromagnetic layer on the non-magnetic layer; and
(d) annealing the perpendicular magnetic recording medium to form an antiferromagnetic oxide in the ferromagnetic layer.

14. The method according to claim 13, wherein the non-magnetic layer in the step (b) is formed by a magnetron sputtering method.

15. The method according to claim 13, wherein the ferromagnetic layer in the step (c) is formed by a magnetron sputtering method.

16. The method according to claim 13, wherein an annealing temperature in the step (d) is between 275° C. and 400° C.

17. The method according to claim 13, wherein the annealing in step (d) is carried out in a vacuum of 0.1 mTorr to 20 mTorr.

18. The method according to claim 13, wherein an annealing time in step (d) is between 5 minutes and 60 minutes.

19. A perpendicular magnetic recording medium, comprising:
a substrate;
a non-magnetic layer formed on the substrate;
a ferromagnetic layer formed on the non-magnetic layer; and
an antiferromagnetic oxide formed in the ferromagnetic layer by an annealing process and generating an exchange coupling interaction with the ferromagnetic materials.

20. The perpendicular magnetic recording medium according to claim 19, wherein the annealing process is performed after the ferromagnetic layer is formed.
